(19) United States
(12) Patent Application Publication
(10) Pub. No.: US 2008/0185727 A1
(43) Pub. Date: Aug. 7, 2008

(54) Semiconductor device capable of selecting wiring connection mode by controlling via formation

(75) Inventor: Tadashi Haruki, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/068,439

(22) Filed: Feb. 6, 2008

(30) Foreign Application Priority Data
Feb. 7, 2007 (JP) 2007-027899

(51) Int. Cl. H01L 21/768; H01L 23/52

(52) U.S. Cl. 257/773; 438/620; 257/E23.141; 257/E21.576

(57) ABSTRACT

In a semiconductor device including an upper-layer wiring and a lower-layer wiring that overlaps the upper-layer wiring, an wiring switching option includes a via extending from the upper-layer wiring toward the lower-layer wiring. The wiring switching option switches a wiring connection state according to whether the via extends from the upper-layer wiring to reach the lower-layer wiring or extends from the upper-layer wiring to terminate in between the upper-layer wiring and the lower-layer wiring.

This application is based upon and claims the benefit of priority from Japanese patent application No. 2007-027899, filed on Feb. 7, 2007, the disclosure of which is incorporated herein in its entirety by reference.

### BACKGROUND OF THE INVENTION

This invention relates to a semiconductor device and, in particular, to a semiconductor device capable of selecting a wiring connection mode.

High integration of semiconductor devices has been progressing year by year, while the scale of the devices also has been increased. On the other hand, an increased variety of customers' demands requires customization of semiconductor devices. The customization of semiconductor devices may be achieved, for example, by a master slice method in which the connection mode of transistor elements or circuit blocks arranged on a common master chip can be made selectable by changing wiring layers or vias. According to the master slice method, only masks have to be customized to be used in the steps of forming wiring layers or vias. The method is therefore advantageous in being capable of reducing the man-hours or period required for development of the semiconductor device. However, as the quantity of wiring layers is increased, the master slice method has also become suffering from problems of increased man-hours or period of development. Accordingly, there has arisen a demand for a method enabling easier selection of wiring connection modes.

Technologies relating to wiring methods of semiconductor devices are described in various patent documents as follows. Patent Document 1 (Japanese Laid-Open Patent Publication 2004-79846) discloses a technique in which there are provided a plurality of sets of combination of a via between a first layer and a second layer, a second-layer metal wiring pad, and a via between the second layer and a third layer. Patent Document 2 (JP 2006-80436A) discloses a technique in which an element electrode is formed by a lower-layer metal wiring which is connected to an upper-layer metal wiring through a via according to a circuit connection. Patent Document 3 (Japanese Laid-Open Patent Publication 2002-299457) discloses a technique in which a commonly usable wiring is connected by a lower-layer metal wiring, while a customizing wiring is connected by an upper-layer metal wiring.

However, according to the techniques described in these patent documents, the wiring connection mode, which is planar, requires an auxiliary wiring track.

### SUMMARY OF THE INVENTION

It is therefore an exemplary object of the invention to provide a semiconductor device capable of selecting a wiring connection mode without the need of additional wiring tracks.

Other objects of the invention will become clear as the description proceeds.

A semiconductor device according to an exemplary aspect of the invention includes an upper-layer wiring, a lower-layer wiring that overlaps the upper-layer wiring, and an wiring switching option that includes a via extending from the upper-layer wiring toward the lower-layer wiring, wherein the wiring switching option switches a wiring connection state according to whether the via extends from the upper-layer wiring to reach the lower-layer wiring or extends from the upper-layer wiring to terminate in between the upper-layer wiring and the lower-layer wiring.

A wiring switching option according to an exemplary aspect of the invention is for switching the wiring connection state between the connected and non-connected state, wherein a via provided in an overlap portion where an upper-layer wiring and a lower-layer wiring overlap each other is formed to reach the lower-layer wiring to establish the connected state between the upper-layer wiring and the lower-layer wiring, and an intermediate wiring is provided so that a via is formed to reach the intermediate wiring but not to the lower-layer wiring to establish the non-connected state between the upper-layer wiring and the lower-layer wiring.

A method according to an exemplary aspect of the invention is of manufacturing a semiconductor device and includes forming a lower-layer wiring, forming an intermediate wiring, forming a via reaching the lower-layer wiring while at the same time forming a via reaching the intermediate wiring but not reaching the lower-layer wiring, and forming an upper-layer wiring.

### BRIEF DESCRIPTION OF THE DRAWINGS

FIG. 1A is a plan view showing a semiconductor device according to a first exemplary embodiment of this invention, which is set to the non-connected state by a wiring switching option;

FIG. 1B is a cross-sectional view taken along the line Ib-Ib in FIG. 1A;

FIG. 1C is a plan view of the semiconductor device shown in FIG. 1A when it is set to the connected state by the wiring switching option;

FIG. 1D is a cross-sectional view taken along the line Id-Id in FIG. 1C;

FIG. 2A is a plan view showing a semiconductor device according to a second exemplary embodiment of this invention, which is set to the non-connected state by a wiring switching option;

FIG. 2B is a plan view showing the semiconductor device in the non-connected state;

FIG. 3A is a plan view of a semiconductor device according to a prior art, which is set to the non-connected state by a wiring switching option; and

FIG. 3B is a plan view showing the semiconductor device of FIG. 3A in the connected state.

### DESCRIPTION OF THE EXEMPLARY EMBODIMENTS

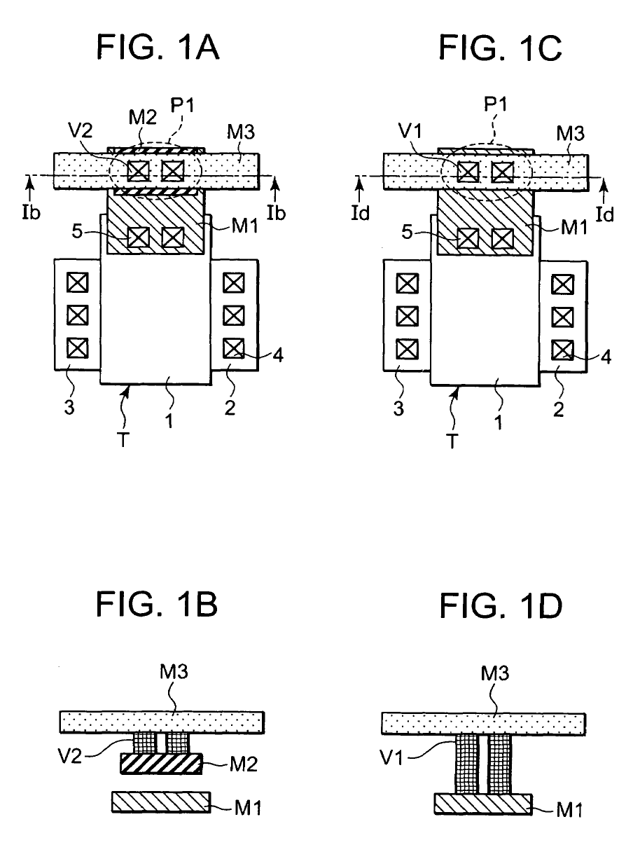

Referring to FIGS. 1A to 1D, a semiconductor device according to a first exemplary embodiment of this invention will be described.

The semiconductor device shown in FIGS. 1A to 1D includes a transistor T as a semiconductor element. The transistor T includes a gate electrode 1, a drain diffusion layer 2, and a source diffusion layer 3. The drain diffusion layer 2 and the source diffusion layer 3 are connected to a drain wiring and a source wiring (not shown), respectively, through contacts 4. The gate electrode 1 is connected, through vias 5, to a first-layer metal wiring M1, or a lower-layer wiring. A main wiring track is defined above the first-layer metal wiring M1, and a third-layer metal wiring M3, which is connectable to the first-layer metal wiring M1 by way of vias, is arranged in the main wiring track as an upper-layer wiring. A wiring switching option P1 is provided in an overlap portion where the first-layer metal wiring M1 and the third-layer metal wiring M3 overlap each other in order to render selectable the connection state of the gate electrode 1 and the drain wiring of the transistor T between the connected and non-connected states.

A comparison will be made between a case in which the first-layer metal wiring M1 and the third-layer metal wiring M3 are connected and a case in which they are not connected.

In the case in which they are not connected as shown in FIGS. 1A and 1B, a second-layer metal wiring M2, which is an intermediate layer, is arranged as an intermediate wiring between the first-layer metal wiring M1 and the third-layer metal wiring M3 in the wiring switching option P1 in correspondence with the vias. A via V2 is formed to extend downward from the third-layer metal wiring M3 only to reach the second-layer metal wiring M2. This connects the second-layer metal wiring M2 and the third-layer metal wiring M3 through the via V2, whereas the first-layer metal wiring M1 and the third-layer metal wiring M3 are not connected to each other.

In the case in which the first-layer metal wiring M1 and the third-layer metal wiring M3 are connected as shown in FIGS. 1C and 1D, no second-layer metal wiring M2 is provided. Accordingly, a via V1 is formed to extend downward from the third-layer metal wiring M3 to reach the first-layer metal wiring M1, whereby the first-layer metal wiring M1 and the third-layer metal wiring M3 are connected to each other.

The difference between the connected and non-connected states is attributable to whether the second wiring layer M2, that is the intermediate wiring, is provided or not. A description will be made of the difference attributable to whether or not the second wiring layer M2, that is the intermediate wiring, is provided in accordance with the manufacturing steps. The first-layer metal wiring M1, that is the lower-layer wiring, is formed and then a first interlayer insulation film is formed thereon. Further, the second-layer metal wiring M2 is formed, and a second interlayer insulation film is formed thereon. The second-layer metal wiring M2 is provided only at a position of the vias not involved in the wiring connection, whereas no second-layer metal wiring M2 is provided at a position the vias involved in the wiring connection.

In a via forming step for connecting the first-layer metal wiring M1 and the third-layer metal wiring M3, a via hole is formed by etching the interlayer insulation film. When the second-layer metal wiring M2 is provided, the etching is stopped at the second-layer metal wiring M2. On the other hand, when no second-layer metal wiring M2 is provided, the etching proceeds to the surface of the first-layer metal wiring M1. In this manner, the vias V1 and V2 having different depths are formed depending on whether the second-layer metal wiring M2 is provided or not.

Vias are formed by filling the via holes with a conductive material. The third-layer metal wiring M3 is formed thereon. When the second-layer metal wiring M2 is provided, the via V2 extends to the second-layer metal wiring M2 to connect the second-layer metal wiring M2 to the third-layer metal wiring M3. Accordingly, the first-layer metal wiring M1 and the third-layer metal wiring M3 are not connected to each other. When no second-layer metal wiring M2 is provided, the via V1 extends to the first-layer metal wiring M1 to connect the first-layer metal wiring M1 to the third-layer metal wiring M3. In this manner, when the via hole are formed by the etching in the same via forming step, the via holes will have different depths depending on whether the second-layer metal wiring M2 is provided or not. The difference in the depths of the via holes causes the difference in the metal wiring layer to be connected, whereby it is made possible to select or switch the connection state of the first-layer metal wiring M1 and the third-layer metal wiring M2 between the connected and non-connected states.

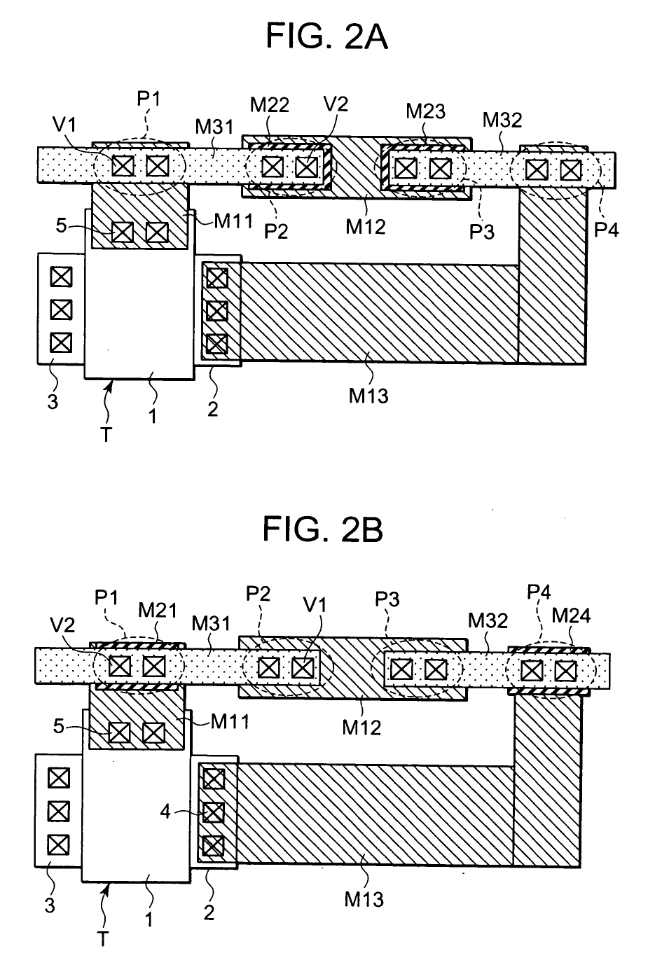

Referring to FIGS. 2A and 2B, a semiconductor device according to a second exemplary embodiment of this invention will be described. Like parts and components are designated with the same reference numerals and characters and description thereof will be omitted.

The semiconductor device shown in FIGS. 2A and 2B includes four wiring switching points to make selectable the connection state between the gate electrode 1 and the drain wiring of the transistor T between the connected and non-connected states. The wiring switching points are provided, respectively, with wiring switching options P1 to P4. The connection between the first-layer metal wiring M12 and third-layer metal wirings M31 and M32 is switched between the non-connected and connected states depending on whether or not the wiring switching options P1 to P4 are provided with the second-layer metal wirings M22 and M23 as intermediate wirings.

The drain diffusion layer 2 of the transistor T is connected to the first-layer metal wiring M13 through the contacts 4. The source diffusion layer 3 of the transistor T is connected to a wiring not shown through the contacts 4. The gate electrode 1 of the transistor T is connected to the first-layer metal wiring M11 through the vias 5.

A main wiring track is defined above the first-layer metal wiring M11, and the third-layer metal wiring M31 which is connectable to the first-layer metal wiring M11 through the vias is arranged on the main wiring track. Further, the first-layer metal wiring M12 and the third-layer metal wiring M32 are arranged on the main wiring track.

Vias are provided in a cross-over region (overlap portion) where the first-layer metal wiring M11 overlaps with the third-layer metal wiring M31, forming a first wiring switching option P1. Vias are provided in an overlap portion where the first-layer metal wiring M12 overlaps with the third-layer metal wiring M31, forming a second wiring switching option P2. Vias are provided in an overlap portion where the first-layer metal wiring M12 overlaps with the third-layer metal wiring M32, forming a third wiring switching option P3. Vias are provided in an overlap portion where the first-layer metal wiring M13 overlaps with the third-layer metal wiring M32, forming a fourth wiring switching option P4. These wiring switching options P1 to P4 make it possible to select or switch the connection state between the first-layer metal wiring and the third-layer metal wiring between the connected and non-connected states according to whether the second-layer metal wiring is provided or not.

When the transistor T is used, the first-layer metal wiring M11 is connected to the third-layer metal wiring M31, and the first-layer metal wiring M13 is connected to the third-layer metal wiring M32. For this purpose, as shown in FIG. 2A, the second-layer metal wiring is not provided in the wiring switching options P1 and P4. The second-layer metal wiring M22 and M23 are provided in the wiring switching options P2 and P3, whereby the gate electrode 1 of the transistor T is connected to the third-layer metal wiring M31, and the drain diffusion layer 2 is connected to the third-layer metal wiring M32. In this condition, the first-layer metal wiring M12 is not used and remains open.

When the transistor T is not used, the first-layer metal wiring M1 connected to the gate electrode 1 is disconnected from the third-layer metal wiring M31, while the first-layer metal wiring M13 connected to the diffusion layer 2 is disconnected from the third-layer metal wiring M32, whereby both the third-layer metal wiring M31 and M13 are made open. For this purpose, as shown in FIG. 2B, the second-layer metal wiring M21 and M24 are provided in the wiring switching options P1 and P4, while no second-layer metal wiring is provided in the wiring switching options P2 and P3. In this condition, the main wiring track is provided with the third-layer metal wiring M31, the first-layer metal wiring M12, and the third-layer metal wiring M32 to be usable as wiring regions for different signals.

The semiconductor device described above includes a plurality of wiring layers and a plurality of wiring switching options. Each of the wiring switching options connects the lower-layer metal wiring to the upper-layer metal wiring by forming vias in a region where the lower-layer metal wiring overlaps with the upper-layer metal wiring. When the lower-layer metal wiring and the upper-layer metal wiring are not connected to each other, an intermediate metal wiring is provided in a region where the lower-layer metal wiring overlaps with the upper-layer metal wiring, while the vias are formed to extend only to the intermediate metal wiring, so that the lower-layer metal wiring is not connected to the upper-layer metal wiring. In this manner, it is made possible to switch the connection state between the lower-layer metal wiring and the upper-layer metal wiring according to whether the intermediate metal wiring is provided or not.

Each of the wiring switching options is composed of a lower-layer metal wiring, an intermediate metal wiring, an upper-layer metal wiring, and vias for connecting the metal wirings. The vias have different depths depending on whether the intermediate metal wiring is provided or not, whereby the wiring connection is switched between the connected and non-connected states. The wiring switching options is formed by vertically stacking the lower-layer metal wiring, the intermediate metal wiring, the upper-layer metal wiring, and the vias for connecting these wirings. The vertically stacked formation of the wiring switching option eliminates the need of excess wiring tracks, making it possible to provide a compact wiring switching option. Further, the cost can be reduced when any correction is done for the semiconductor device by switching the signal lines by means of the intermediate metal wiring which is roughly patterned and does not require fine patterning.

Some exemplary embodiments of the invention will be enumerated below.

A third exemplary embodiment of the invention is a semiconductor device in which the via reaches the lower-layer wiring to connect the upper-layer wiring to the lower-layer wiring.

A fourth exemplary embodiment of the invention is a semiconductor device comprising an intermediate wiring arranged between the upper-layer wiring and the lower-layer wiring, wherein the via extends from the upper-layer wiring to terminate at the intermediate wiring, and does not connect the upper-layer wiring to the lower-layer wiring.

A fifth exemplary embodiment of the invention is a semiconductor device in which an upper-layer wiring track defines a position where the upper-layer wiring is to be laid, wherein the wiring switching option is placed on the upper-layer wiring track, the upper-layer wiring is arranged on the upper-layer wiring track, the intermediate wiring is arranged to overlap the upper-layer wiring and in parallel thereto.

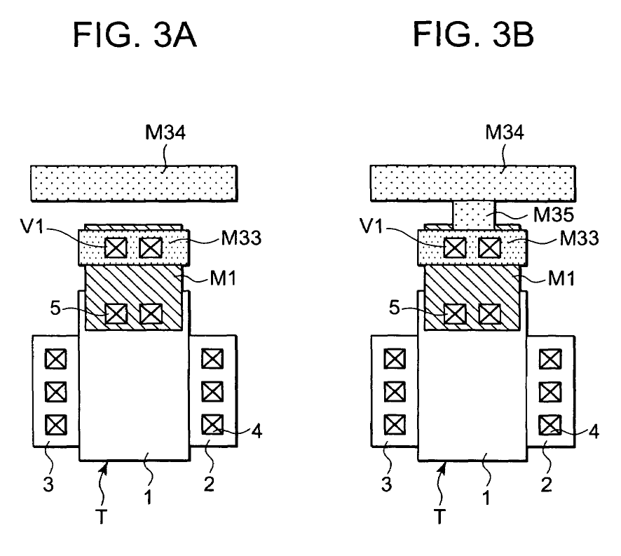

Referring to FIGS. 3A and 3B here, a description will be made of a master slice method as a related technology. The master slice method enables the selection of whether or not the transistor T is connected to the upper or third-layer metal wiring M34. FIG. 3A shows the non-connected state, whereas the FIG. 3B shows the connected state.

The transistor T includes a gate electrode 1, a drain diffusion layer 2, and a source diffusion layer 3. The drain diffusion layer 2 and the source diffusion layer 3 are connected to respective wiring lines (not shown) through contacts 4. The gate electrode 1 is connected to a first-layer metal wiring M1 through vias 5. The first-layer metal wiring M1 is connected to a third-layer metal wiring M33 through vias V1. Further, a third-layer metal wiring M34 is laid on the main wiring track. The term “wiring track” means a position where wirings are to be laid, which is predetermined according to a certain rule. The automated wiring layout is made easier by determining the position where the wirings can be laid as the wiring track in this manner.

In the non-connected state shown in FIG. 3A, the third-layer metal wiring M34 and the third-layer metal wiring M33 are not connected to each other. In the connected state shown in FIG. 3B, the third-layer metal wiring M33 and the third-layer metal wiring M34 are connected to each other through a third-layer metal wiring M35 arranged in an auxiliary wiring track. Accordingly, the connection state between the third-layer metal wiring M33 and the third-layer metal wiring M34 can be switched between the connected and non-connected states according to whether the third-layer metal wiring M35 is provided or not. In this manner, the third-layer metal wiring M33 and the third-layer metal wiring M34 are connected planarly to each other by means of the third-layer metal wiring M35.

However, the master slice method as described above incurs several problems as follows. One of the problems is that an auxiliary wiring track is required because of the planar connection. Another problem is that the use of the wiring layer requiring fine patterning increases the manufacturing cost.

On the other hand, the semiconductor device according to the invention includes an intermediate wiring layer for controlling the depth of vias to determine whether or not the vias reach the lower-layer wiring so that the connection state between the upper-layer wiring and the lower-layer wiring is switched between the connected and non-connected states. This wiring switching option, that is formed vertically, has an exemplary advantage that the wiring switching option can be formed in a reduced space without using any excess wiring track. Further, an additional exemplary advantage is obtained that the intermediate wiring layer can be formed roughly without requiring any fine patterning and hence the cost required for possible correction can be reduced.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

What is claimed is:

1. A semiconductor device comprising:
an upper-layer wiring;
a lower-layer wiring that overlaps the upper-layer wiring; and
an wiring switching option that includes a via extending from the upper-layer wiring toward the lower-layer wiring,
wherein the wiring switching option switches a wiring connection state according to whether the via extends from the upper-layer wiring to reach the lower-layer wiring or extends from the upper-layer wiring to terminate in between the upper-layer wiring and the lower-layer wiring.

2. The semiconductor device according to claim 1, wherein the via reaches the lower-layer wiring to connect the upper-layer wiring to the lower-layer wiring.

3. The semiconductor device according to claim 1, further comprising an intermediate wiring arranged between the upper-layer wiring and the lower-layer wiring.

4. The semiconductor device according to claim 3, wherein the via extends from the upper-layer wiring to terminate at the intermediate wiring, and does not connect the upper-layer wiring to the lower-layer wiring.

5. The semiconductor device according to claim 3, wherein the intermediate wiring is connected only to the upper-layer wiring and not to any other wiring.

6. The semiconductor device according to claim 3, wherein the intermediate wiring is arranged to overlap the upper-layer wiring and in parallel thereto.

7. The semiconductor device according to claim 1, wherein an upper-layer wiring track defines a position where the upper-layer wiring is to be laid, wherein the wiring switching option is placed on the upper-layer wiring track.

8. The semiconductor device according to claim 7, wherein the upper-layer wiring is arranged on the upper-layer wiring track.

9. The semiconductor device according to claim 7, further comprising an intermediate wiring arranged between the upper-layer wiring and the lower-layer wiring.

10. The semiconductor device according to claim 9, wherein the via extends from the upper-layer wiring to terminate at the intermediate wiring, and does not connect the upper-layer wiring to the lower-layer wiring.

11. The semiconductor device according to claim 9, wherein the intermediate wiring is connected only to the upper-layer wiring and not to any other wiring.

12. The semiconductor device according to claim 9, wherein the intermediate wiring is arranged to overlap the upper-layer wiring and in parallel thereto.

13. The semiconductor device according to claim 1, further comprising a semiconductor element connected to the lower-layer wiring.

14. The semiconductor device according to claim 1, wherein the lower-layer wiring extends in a direction orthogonal to the upper-layer wiring.

15. The semiconductor device according to claim 14, further comprising an intermediate wiring arranged between the upper-layer wiring and the lower-layer wiring.

16. The semiconductor device according to claim 15, wherein the via extends from the upper-layer wiring to terminate at the intermediate wiring, and does not connect the upper-layer wiring to the lower-layer wiring.

17. The semiconductor device according to claim 15, wherein the intermediate wiring is connected only to the upper-layer wiring and not to any other wiring.

18. The semiconductor device according to claim 15, wherein the intermediate wiring is arranged to overlap the upper-layer wiring and in parallel thereto.

19. A wiring switching option for switching the wiring connection state between the connected and non-connected state, wherein a via provided in an overlap portion where an upper-layer wiring and a lower-layer wiring overlap each other is formed to reach the lower-layer wiring to establish the connected state between the upper-layer wiring and the lower-layer wiring, and an intermediate wiring is provided so that a via is formed to reach the intermediate wiring but not to the lower-layer wiring to establish the non-connected state between the upper-layer wiring and the lower-layer wiring.

20. A method of manufacturing a semiconductor device, comprising:
forming a lower-layer wiring;
forming an intermediate wiring;
forming a via reaching the lower-layer wiring while at the same time forming a via reaching the intermediate wiring but not reaching the lower-layer wiring; and
forming an upper-layer wiring.
